(19) United States
(12) Patent Application Publication
(10) Pub. No.: US 2017/0363874 A1
(43) Pub. Date: Dec. 21, 2017

(54) MODULAR HEADS UP DISPLAY ASSEMBLIES

(71) Applicant: SYMBOL TECHNOLOGIES, LLC, LINCOLNSHIRE, IL (US)

(72) Inventors: NICOLE D. TRICOUKES, SEAFORD, NY (US); JAEHO CHOI, WHITESTONE, NY (US)

(21) Appl. No.: 15/188,583

(22) Filed: Jun. 21, 2016

(51) Int. Cl. G02B 27/01; H05K 5/02; H05K 5/00

(52) U.S. Cl. CPC G02B 27/0176; H05K 5/0017; H05K 5/0217; G02B 27/0172; G02B 2027/014; G02B 2027/0169; G02B 2027/0178

(57) ABSTRACT

Modular heads up display (HUD) assemblies are disclosed herein. An example apparatus disclosed herein includes a housing to carry an image generator; a display surface extending from a first side of the housing; and a mating surface along a second side of the housing opposing the first side of the housing, the mating surface to removably couple a head mount to the housing.

### FIELD OF THE DISCLOSURE

This disclosure relates generally to wearable electronic devices and, more particularly, to modular heads up display assemblies.

### BACKGROUND

Recent advances in processing technology have improved the viability and usability of wearable electronic devices such as, for example, heads-up display (HUD) devices and systems.

### BRIEF DESCRIPTION OF THE DRAWINGS

FIG. 1 is a block diagram representative of an example modular heads up display (HUD) assembly in communication with a network and external devices.

FIG. 2A is a perspective view of an example modular HUD assembly disclosed herein.

FIG. 2B is another perspective view of the example modular HUD assembly of FIG. 2A.

FIG. 2C is another perspective view of the example modular HUD assembly of FIG. 2A.

FIG. 3 is another perspective view of the example modular HUD assembly of FIG. 2A.

FIG. 4 is another perspective view of the example modular HUD assembly of FIGS. 2 and 3.

FIG. 5 is another perspective view of the example modular HUD assembly of FIGS. 2-4.

FIG. 6 is a perspective view of an example modular HUD assembly disclosed herein.

FIG. 7 is a perspective view of the example modular HUD assembly of FIG. 6.

FIG. 8 is a perspective view of an example modular HUD assembly disclosed herein.

FIG. 9 is a perspective view of an example modular HUD assembly disclosed herein in a first position.

FIG. 10 is a perspective view of the example modular HUD assembly of FIG. 9 in a second position.

FIG. 11 is a perspective view of the example modular HUD assembly of FIGS. 9 and 10.

FIG. 12 is a perspective view of the example modular HUD assembly of FIGS. 9-11.

FIG. 13 is a perspective view of an example modular HUD assembly disclosed herein.

FIG. 14 is a perspective view of an example modular HUD assembly disclosed herein.

FIG. 15 is a perspective view of an example modular HUD assembly disclosed herein.

FIG. 16 is a perspective view of an example pad disclosed herein for use with example HUD assemblies disclosed herein.

FIG. 17 is a perspective view of the example pad of FIG. 16 installed on an example HUD assembly disclosed herein.

FIG. 18 is a perspective view of an example power assembly disclosed herein for use with example HUD assemblies disclosed herein.

FIG. 19 is a block diagram of an example logic circuit for capable of implementing electronic components of example HUD assemblies disclosed herein.

### DETAILED DESCRIPTION

Heads up display (HUD) technology is employed across a range of industries and applications. For example, HUD technology is utilized in enterprise applications, such as warehousing, field service, healthcare, retail, and manufacturing, as well as personal (i.e., consumer) applications. The range of applications in which HUD technology is employed involves deploying HUD devices into different environments, each of which entails a unique set of conditions, type of users, and circumstances. As such, each different environment or deployment imposes unique requirements, challenges and demands on the HUD devices.

Example modular HUD assemblies disclosed herein provide versatility and adaptable to HUD technology. As described in detail below, example modular HUD assemblies disclosed herein enable HUD devices to employ interchangeable components without interfering with operations or capabilities (e.g., field of view). For example, the modular configuration of example HUD assemblies disclosed herein enables use of a variety of individual head mounts with a same display component (e.g., a presentation generator including an optical waveguide) while providing a desirable field of view for a user. Advantageously, each of the heat mounts is tailored for one or more specific applications. That is, example modular HUD assemblies disclosed herein enable pairing of a central component (e.g., a display component and/or housing carrying the display component) with different peripheral components, each of which can be customized for a particular environment, application, industry, usage, type of user, and/or any other factor. In some examples disclosed herein, different head mounts having different form factors and/or hygienic elements are each capable of mounting a same presentation generator (e.g., a housing carrying light engines and an optical waveguide) to a head of a user. Accordingly, the same presentation generator is adaptably usable across different applications, while the HUD assembly as a whole (e.g., the combination of the display components and the head mount) is tailored specifically for individual ones of the different applications.

In addition to the modularity provided by example HUD assemblies disclosed herein, example apparatus disclosed herein include beneficial and advantageous structures, arrangements, designs, and configurations for HUD devices and applications. As described in detail below, example display components disclosed herein include image generators (e.g., light engines) positioned along an upper edge of the display component. That is, the image generators of example display components disclosed herein are located above image receiving surfaces (e.g., lenses of an optical waveguide) when the display component is placed in an orientation in which a user is expected to wear the HUD device (e.g., as mounted to a head of the user). By locating the image generators along the upper edge, example HUD assemblies disclosed herein do not interfere with the field of view of the user. For example, using example HUD assemblies disclosed herein having the image generators mounted to the upper edge do not obstruct peripheral portions of the field of view. Moreover, as the side edges of the display component are not occupied by image generators, the example interface structure(s) disclosed herein enable a user to wear glasses under the HUD assembly. This configuration of example HUD assemblies disclosed herein contrasts with known HUD devices having image generators mounted on side edges that obstruct portions of the field of view and prevent user from wearing glasses (e.g., prescription glasses).

As described in greater detail below, example HUD assemblies disclosed herein include one or more interface structures configured to removably couple to a display component (e.g., a presentation generator including light engine(s) and an optical waveguide) along an upper edge of the display component. Example interface structures disclosed herein and the positioning thereof (e.g., along the upper edge, as opposed to side edges, of the display component) does not obstruct peripheral portions of the field of view of the user. Moreover, as the interface structures are located along the upper edge rather than the side edges of the display component, the example interface structure(s) disclosed herein enable a user to wear glasses (e.g., prescription glasses) under the HUD assembly. In some examples, the interface structure(s) disclosed herein enable attachment of a one-piece head mount that is conveniently detachable using, for example, only a single hand of the user.

As described in greater detail below, example hinged head mounts disclosed herein enable different positions or states for HUD assemblies. Example hinged head mounts disclosed herein provide an option to move the display component (e.g., a presentation generator including light engines and an optical waveguide) from a viewing position to a stowed position by, for example, pivoting a display component out of a field of view of the user. By providing the stowed position, example hinged head mounts disclosed herein enable a user to remove the display component from at least a portion of the field of view of the user, while enabling fast and convenient re-engagement of the display component into the field of view of the user.

As described in greater detail below, example cable guides disclosed herein route one or more cables (e.g., data cables or power cables) to a rear portion of head mounts such that the cables are guided towards a back of a user. In some HUD devices, a cable extends from a port of the HUD device to, for example, a processing component mounted to a belt worn by the user. Examples disclosed herein that route the cable(s) toward the rear of the head mounting component position the cable(s) to be draped down the back of the user and, thus, away from the space in front of the user in which work is being performed. That is, examples disclosed herein provide a working space in front of the user that is not hindered or interfered with by cable(s) dangling from the HUD device.

As described in detail below, example pads disclosed herein are configured to be located between a head of a user and a HUD assembly. Example pads disclosed herein have form factors that correspond to a shape of one or more elements (e.g., a housing of image generators such as light engines) of the HUD assembly. Example pads disclosed herein enhance comfort of the user wearing the HUD assembly. Moreover, as some HUD assemblies are shared between different users, example pads disclosed herein provide hygienic benefits.

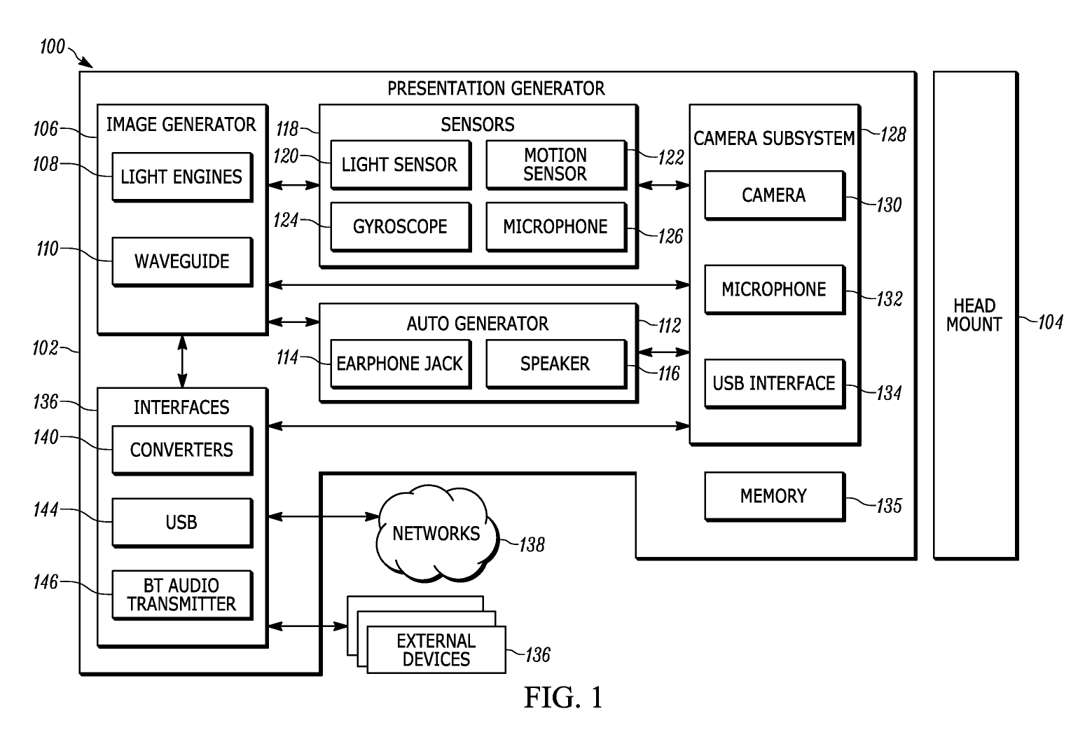

FIG. 1 is a block diagram of an example HUD assembly 100 constructed in accordance with teachings of this disclosure. Alternative implementations of the example HUD assembly 100 of FIG. 1 include one or more additional or alternative elements, processes and/or devices. In some examples, one or more of the elements, processes and/or devices of the example HUD assembly 100 of FIG. 1 may be combined, divided, re-arranged or omitted.

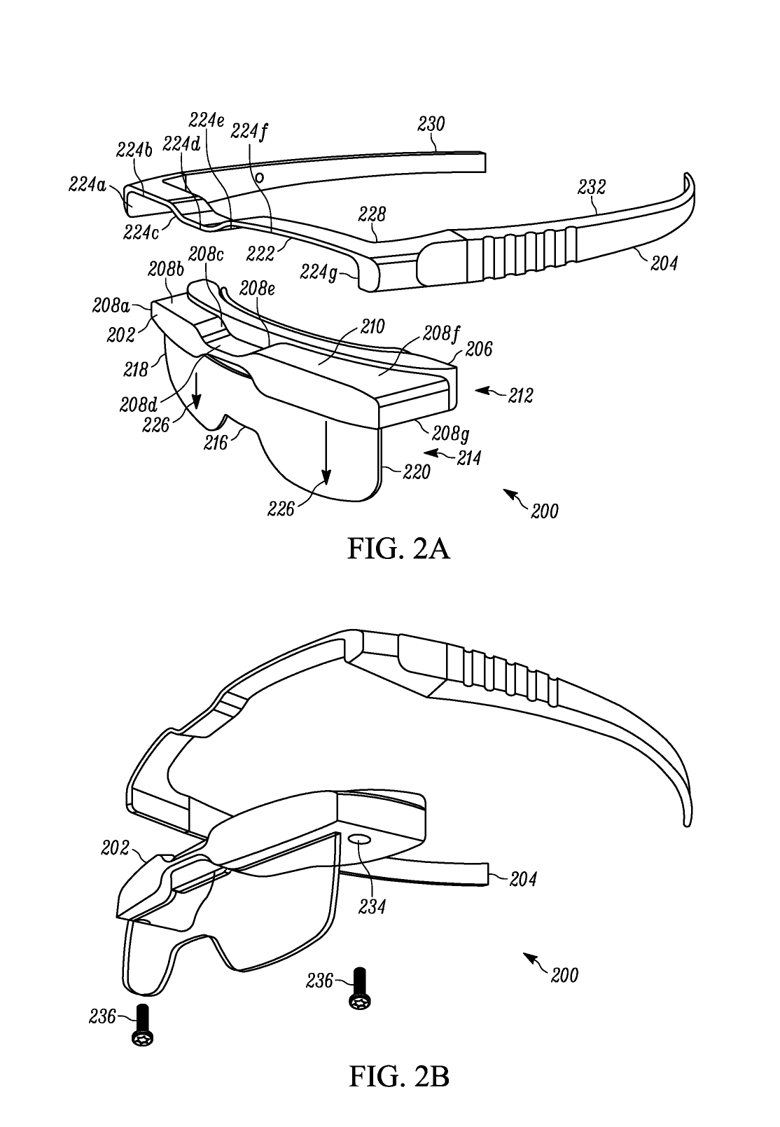

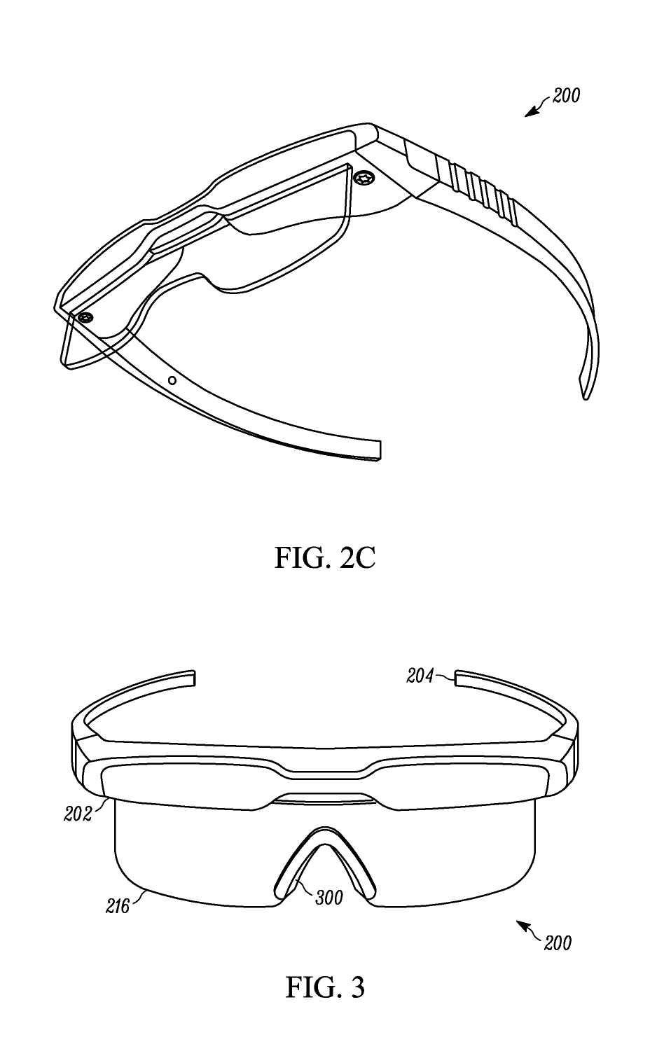

The example HUD assembly 100 of FIG. 1 includes a presentation generator 102 and a head mount 104. The example HUD assembly 100 of FIG. 1 is modular in that different versions, instantiations and/or implementations of the head mount 104 are usable with the example presentation generator 102. Additionally, the example HUD assembly 100 of FIG. 1 is modular in that different versions, instantiations and/or implementations of the presentation generator 102 are usable with the example head mount 104. The modularity of the example HUD assembly 100 of FIG. 1 and example implementations enabled by the modularity of the example HUD assembly 100 of FIG. 1 are described in detail below in connection with FIGS. 2-17.

The head mount 104 is constructed to mount the presentation generator 102 to a head of a person such that a presentation generated by the presentation generator 102 is consumable by the person. The presentation includes visual media components (e.g., images) and/or audio media components. To generate images such as static or animated text and/or graphics, the example presentation generator 102 of FIG. 1 includes an image generator 106. The example image generator 106 of FIG. 1 is in communication with one or more sources of image data. The image data received at the image generator 106 is representative of, for example, text, graphics and/or augmented reality elements (e.g., information overlaid on objects within the field of view). The example image generator 106 of FIG. 1 includes light engines 108 that convert the received image data into patterns and pulses of light. The light engines 108 communicate the generated light to a waveguide 110, such that the images corresponding to the received data are displayed to the user via the waveguide 110. In some examples, the light engines 110 include optics that condition or manipulate (e.g., polarize and/or collimate) the generated light prior to providing the light to the waveguide 110. While the example image generator 106 utilizes the light engines 108 and the waveguide to present visual components of the presentation, the example HUD assembly 100 of FIG. 1 can employ any suitable image generating technology such as, for example, cathode ray tube (CRT) devices or scanning lasers.

In the example of FIG. 1, the light engines 108 utilize a light source (e.g., light emitting diodes (LEDs)) to generate light based on the received data. In some examples, the light engines 108 receive processed data in condition for immediate conversion into light. In some examples, the light engines 108 process raw image data before converting the image data into light. To perform such processing, the example light engines 108 of FIG. 1 include and/or are in communication with one or more logic circuits configured to process the image data.

The example waveguide 110 of FIG. 1 carries the light received from the light engines 108 in a direction and pattern corresponding to the image data. In the illustrated example, the waveguide 110 includes a plurality of internal surfaces that form a light guide to internally reflect the light as the light travels from an input to an output. The example waveguide 110 includes gratings at the output to diffract the light towards an eye of the user, thereby displaying the image to the user. The example waveguide 110 of FIG. 1 includes first and second lenses arranged to be placed over first and second eyes, respectively, of the user. However, any suitable shape or size is possible for the waveguide 110. In the illustrated example, the waveguide 110 is transparent such that the user can view surroundings simultaneously with the displayed image, or the surroundings only when no image is displayed on the waveguide 110.

The example presentation generator 102 of FIG. 1 includes an audio generator 112 that receives audio data and converts the audio data into sound via an earphone jack 114 and/or a speaker 116. In some examples, the audio generator 112 and the image generator 106 cooperate to generate an audiovisual presentation.

In the example of FIG. 1, the example presentation generator 102 includes (e.g., houses) a plurality of sensors 118. In the example of FIG. 1, the plurality of sensors 118 include a light sensor 122, a motion sensor 124 (e.g., an accelerometer), a gyroscope 126 and a microphone 128. In some examples, the presentation generated by the example image generator 106 and/or the audio generator 112 is affected by one or more measurements and/or detections generated by one or more of the sensors 118. For example, a characteristic (e.g., degree of opacity) of the display generated by the image generator 106 may depend on an intensity of ambient light detected by the light sensor 120. Additionally or alternatively, one or more modes, operating parameters, or settings are determined by measurements and/or detections generated by one or more of the sensors 118. For example, the presentation generator 102 may enter a standby mode if the motion sensor 122 has not detected motion in a threshold amount of time.

The example presentation generator 102 of FIG. 1 includes a camera sub-system 128. In some examples, the camera sub-system 128 is mounted to or carried by the same housing as the presentation generator 102. In some examples, the camera sub-system 128 is mounted to or carried by the head mount 104. The example camera sub-system 128 includes a camera 130 and a microphone 132 to capture image data and audio data, respectively, representative of an environment surrounding the HUD assembly 100. In some examples, image and/or audio data captured by the camera 130 and/or microphone 132 is integrated with the presentation generated by the image generator 106 and/or the audio generator 112. For example, the camera sub-system 128 of FIG. 1 communicates data to the image generator 102, which may process the image data and to generate one or more corresponding images on the waveguide 110. In some examples, the image data and/or audio data captured by the camera 130 and/or the microphone 132, respectively, is stored in memory 135 of the example HUD assembly 100. In some examples, the image data and/or audio data captured by the camera 130 and/or the microphone 132, respectively, is communicated via, for example, a USB interface 134 of the camera sub-system 128 to a device (e.g., a server or external memory) external to the HUD assembly 100.

The example presentation generator 102 of FIG. 1 includes a plurality of interfaces 136 configured to enable the HUD assembly 100 to communicate with one or more external devices 136 and one or more networks 138. In the example of FIG. 1, the interfaces 136 include converters 140 (e.g., an HDMI to LVDS-RGB converter) to convert data from one format to another, a USB interface 142, and a Bluetooth® audio transmitter 146. In some examples, the example Bluetooth® audio transmitter 146 cooperates with one or both of the microphones 126, 132 of the HUD assembly 100 to receive voice input from the user and to convey the voice input to one or more of the external devices 136. For example, voice input may be provided to a mobile computing being worn by the user via the HUD assembly 100 using the Bluetooth® audio transmitter 146. Examples external devices 136 include keypads, Bluetooth® click buttons, smart watches, and mobile computing devices.

The example image generator 106, the example light engines 108, the example audio generator 112, the example camera-sub-system 128, the example converts 136, the example USB interfaces 134, 144 and/or, more generally, the example presentation generator 102 of FIG. 1 are implemented by hardware, software, firmware, and/or any combination of hardware, software and/or firmware. In some examples, at least one of the example image generator 106, the example light engines 108, the example audio generator 112, the example camera-sub-system 128, the example converts 136, the example USB interfaces 134, 144 and/or, more generally, the example presentation generator 102 of FIG. 1 is implemented by a logic circuit (e.g., the example processing platform 1900 of FIG. 19). As used herein, the term “logic circuit” is expressly defined as a physical device including at least one hardware component configured (e.g., via operation in accordance with a predetermined configuration and/or via execution of stored machine-readable instructions) to control one or more machines and/or perform operations of one or more machines. Examples of a logic circuit include one or more processors, one or more coprocessors, one or more microprocessors, one or more controllers, one or more digital signal processors (DSPs), one or more application specific integrated circuits (ASICs), one or more field programmable gate arrays (FPGAs), one or more microcontroller units (MCUs), one or more hardware accelerators, one or more special-purpose computer chips, and one or more system-on-a-chip (SoC) devices. Some example logic circuits, such as ASICs or FPGAs, are specifically configured hardware for performing operations. Some example logic circuits are hardware that executes machine-readable instructions to perform operations. Some example logic circuits include a combination of specifically configured hardware and hardware that executes machine-readable instructions.

As used herein, each of the terms “tangible machine-readable medium,” “non-transitory machine-readable medium” and “machine-readable storage device” is expressly defined as a storage medium (e.g., a platter of a hard disk drive, a digital versatile disc, a compact disc, flash memory, read-only memory, random-access memory, etc.) on which machine-readable instructions (e.g., program code in the form of, for example, software and/or firmware) can be stored. Further, as used herein, each of the terms “tangible machine-readable medium,” “non-transitory machine-readable medium” and “machine-readable storage device” is expressly defined to exclude propagating signals. That is, as used in any claim of this patent, a “tangible machine-readable medium” cannot be read to be implemented by a propagating signal. Further, as used in any claim of this patent, a “non-transitory machine-readable medium” cannot be read to be implemented by a propagating signal. Further, as used in any claim of this patent, a “machine-readable storage device” cannot be read to be implemented by a propagating signal.

As used herein, each of the terms “tangible machine-readable medium,” “non-transitory machine-readable medium” and “machine-readable storage device” is expressly defined as a storage medium on which machine-readable instructions are stored for any suitable duration of time (e.g., permanently, for an extended period of time (e.g., while a program associated with the machine-readable instructions is executing), and/or a short period of time (e.g., while the machine-readable instructions are cached and/or during a buffering process)).

FIG. 2A illustrates an example HUD assembly 200 that may implement the example HUD assembly 100 of FIG. 1. The example HUD assembly 200 of FIG. 2A includes a presentation generator 202 and an example head mount 204. The example presentation generator 202 of FIG. 2A houses or carries components configured to generate, for example, an audiovisual presentation for consumption by a user wearing the example HUD assembly 200 of FIG. 2A. For example, the presentation generator 202 of FIG. 2A houses or carries the components of the example presentation generator 102 of FIG. 1.

In the example of FIG. 2A, the presentation generator 202 is configured to be coupled with different head mounts such as, for example, the head mount 204 of FIG. 2A. That is, the example presentation generator 202 includes a modular form factor such that more than one type of head mount is attachable to the presentation generator 202. In the illustrated example, a housing 206 of the presentation generator 202 includes one or more interface structures 208 (e.g., particularly shaped surfaces) positioned along a mating surface 210. Put another way, the example interface structures 208 of FIG. 2A are portions of the mating surface 210. The example interface structures 208 of FIG. 2A are keying features or keying elements that cooperate with counterpart keying features or keying elements of a counterpart structure (e.g., a peripheral module). In some examples, the interface structures 208 define one or more receptacles and/or protrusions that interface with counterpart receptacles and/or protrusions.

In the example of FIG. 2A, the mating surface 210 is located on an upper portion 212 of the presentation generator 202. As used herein, the term “upper portion” refers to a portion located above image receiving surfaces (e.g., lenses of an optical waveguide) when the corresponding HUD assembly (e.g., any of the HUD assemblies disclosed herein) is placed in an orientation in which a user is expected to wear the HUD assembly. More generally, relative terms (e.g., “upper,” “above,” “under,” “below” “side”, “front”, “rear”) used herein are hereby defined to refer to an orientation of the corresponding HUD assembly in which a user is expected to wear the HUD assembly. Further, the terms “vertical”, “horizontal,” “vertically,” “horizontally,” “vertical axis”, “horizontal axis” and their different forms used herein are hereby defined to refer to an orientation of the corresponding HUD assembly in which a user is expected to wear the HUD assembly. The orientation of the HUD assembly in which a user is expected to wear the HUD device is referred to herein as the “worn orientation” or the “mounted orientation.” As such, the upper portion 212 of FIG. 2A is said to be “above” or “over” a lower portion 214 of the HUD assembly 200. Further, the lower portion 214 of the HUD assembly 200 is said to “below” or “beneath” or “under” the upper portion 212. While the HUD assemblies disclosed herein may be placed in different orientations, the relative terms used herein are meant to refer to maintain the respective meanings across the different orientations.

In the example of FIG. 2A, the lower portion 214 includes an optical waveguide 216 coupled to the housing 206. In the example of FIG. 2A, at least a portion of the mating surface 210 is located on a first side of the housing 206 and the waveguide 216 is coupled to and/or extends from a second side of the housing 206 opposing the first side. Moreover, the example HUD assembly 200 of FIG. 2A is said to have first and second side edges 218 and 220, which each extend along the waveguide 216 and the housing 206.

In the example of FIG. 2A, a first interface structure 208a extends along the mating surface 210 in a first direction (e.g., substantially (e.g., within a threshold number of degrees such as five, ten, fifteen or twenty degrees) vertically or along a vertical axis). Further, in the example of FIG. 2A, a second interface structure 208b extends along the mating surface 210 in a second direction (e.g., substantially horizontally or along a horizontal axis). Further, in the example of FIG. 2A, a third interface structure 208c extends along the mating surface 210 in a third direction at an angle relative to the first and second directions (e.g., acutely or obtusely to the vertical or horizontal axis). Further, in the example of FIG. 2A, a fourth interface structure 208d extends along the mating surface 210 in a fourth direction (e.g., substantially horizontally or along the horizontal axis). Further, in the example of FIG. 2A, a fifth interface structure 208e extends along the mating surface 210 in a fifth direction at an angle relative to the first and second directions (e.g., acutely or obtusely to the vertical or horizontal axis). Further, in the example of FIG. 2A, a sixth interface structure 208f extends along the mating surface 210 in a sixth direction (e.g., substantially horizontally or along the horizontal axis). Further, in the example of FIG. 2A, a seventh interface structure 208g extends along the mating surface 210 in a seventh direction (e.g., substantially vertically or along the vertical axis).

The example interface structures 208 of the presentation generator 202 of FIG. 2A are alternatively described as including a first base element, a second base element, and a receptacle located between the first and second base elements. In the example of FIG. 2A, the first base element is defined by a combination of the first interface structure 208a and the second interface structure 208b, the receptacle is defined by the third interface structure 208c, the fourth interface structure 208d and the fifth interface structure 208e, and the second base element is defined by a combination of the sixth interface structure 208f and the seventh interface structure 208g. In the illustrated example of FIG. 2A, the first base element and the second based element may be considered protrusions relative to the receptacle.

In the illustrated example of FIG. 2A, the head mount 204 includes a mating surface 222 having interface structures 224 (e.g., particularly shaped surfaces) configured to matingly engage the interface structures 208 of the presentation generator 202. In the illustrated example of FIG. 2A, the interface structures 208 of the presentation generator 202 are counterpart structures to the interface structures 224 of the head mount 204. In the illustrated example of FIG. 2A, the mating surface 222 extends in a plurality of directions that are counterpart directions to the corresponding ones of the interface structures 208 of the mating surface 210 of the presentation generator 202.

In the example of FIG. 2A, a first interface structure 224a extends along the mating surface 222 in a first direction (e.g., substantially (e.g., within a threshold number of degrees such as five, ten, fifteen or twenty degrees) vertically or along a vertical axis). Further, in the example of FIG. 2A, a second interface structure 224b extends along the mating surface 222 in a second direction (e.g., substantially horizontally or along a horizontal axis). Further, in the example of FIG. 2A, a third interface structure 224c extends along the mating surface 222 in a third direction at an angle relative to the first and second directions (e.g., acutely or obtusely to the vertical or horizontal axis). Further, in the example of FIG. 2A, a fourth interface structure 224d extends along the mating surface 222 in a fourth direction (e.g., substantially horizontally or along the horizontal axis). Further, in the example of FIG. 2A, a fifth interface structure 224e extends along the mating surface 222 in a fifth direction at an angle relative to the first and second directions (e.g., acutely or obtusely to the vertical or horizontal axis). Further, in the example of FIG. 2A, a sixth interface structure 224f extends along the mating surface 222 in a sixth direction (e.g., substantially horizontally or along the horizontal axis). Further, in the example of FIG. 2A, a seventh interface structure 224g extends along the mating surface 222 in a seventh direction (e.g., substantially vertically or along the vertical axis). In the example of FIG. 2A, the first through seventh directions along which the interface structures 224 of the head mount 204 correspond to the first through seventh directions, respectively, along which the interface structures 208 of the presentation generator 208 extend.

The example interface structures 224 of the head mount 204 of FIG. 2A are alternatively described as including a first base element, a second base element, and a protrusion located between the first and second base elements. In the example of FIG. 2A, the first base element of the head mount 204 is defined by a combination of the first interface structure 224a and the second interface structure 224b, the protrusion of the head mount 204 is defined by the third interface structure 224c, the fourth interface structure 224d and the fifth interface structure 224e, and the second base element of the head mount 204 is defined by a combination of the sixth interface structure 224f and the seventh interface structure 224g. In the illustrated example of FIG. 2A, the first base element and the second based element of the head mount 204 may be considered receptacles relative to the protrusion of the head mount 204.

When mated, the example interface structures 208 of the presentation generator 202 and the interface structures 224 of the head mount 204 cooperate to removably couple the head mount 204 to the presentation generator 202. In some examples, the interface structures 208 of the presentation generator 202 and the interface structures 224 of the head mount 204 are configured for a friction fit such that a threshold amount of force is required to decouple the presentation generator 202 from the head mount 204. In some examples, the interface structures 208 of the presentation generator 202 and/or the interface structures 224 of the head mount 204 include one or more retaining members (e.g., tabs, hooks, and/or male/female engagements) to implement a threshold amount of force required to decouple the presentation generator 202 from the head mount 204. In some examples, one or more of the interface structures 208 of the presentation generator 202 and/or one or more of the interface structures 224 of the head mount 204 includes a release element such as, for example, a latch or pin that is engaged (e.g., pressed or moved) to disengage the presentation generator 202 from the head mount 204.

In the example of FIG. 2A, the housing 206 of the presentation generator 202 carries light engines (not shown in FIG. 2A) (e.g., the light engines 108 of FIG. 1) that generate light to be carried by the waveguide 216. In the illustrated example, the light engines direct the light across the waveguide 216 in a direction 226 away from the housing 206. Notably, in the example HUD assembly 200 of FIG. 2A, the light engines are located above the waveguide 216 and the light is directed downward (as opposed to sideways). This position of the light engines contrasts with known light engines that are positioned on side edges of the corresponding HUD assembly. By locating the light engines in the housing 206 (e.g., in the upper portion 212 of the presentation generator 202) and above the waveguide 216, the example HUD assembly 200 of FIG. 2A does not obstruct the field of view of the user. For example, without light engines on the side edges 218 and 220, the user of the example HUD assembly 200 of FIG. 2A has full peripheral vision available in the field of view.

In the example of FIG. 2A, the mating surface 222 and the interface structures 224 thereof make up a coupler 228 that enables first and second rails 230 and 232 to be simultaneously coupled to the presentation generator 202. This contrasts with known glasses in which in which individual rails are detached from a frame one at a time by removing different screws coupling the individual rails to the frame. In some examples, the coupler 228 and the first and second rails 230 and 232 form a modular sub-assembly. That is, the example coupler 228 of FIG. 2A may enable different types of rails to be removably coupled thereto. Alternatively, the example coupler 228 and the first and second rails 230 and 232 may form a one-piece (e.g., a singularly manufactured piece of material or an integrally formed piece of material) head mount 204.

FIG. 2B is another perspective view of the example HUD assembly 200 of FIG. 2A. Additionally, in the example of FIG. 2B, the presentation generator 202 includes apertures 234 configured to receive fasteners 236. In illustrated example, the fasteners 236 engage complimentary receptacles in the head mount 204.

FIG. 2C illustrates the example HUD assembly 200 of FIGS. 2A and 2B with the presentation generator 202 assembled with or coupled to the head mount 204.

FIG. 3 illustrates the example HUD assembly 200 of FIG. 2A with the head mount 204 removably coupled to the presentation generator 202. As shown in FIG. 3, the interface structures 208 of the presentation generator 202 and the interface structures 224 of the head mount 204 are configured (e.g., shaped) to engage each other to couple the presentation generator 202 and the head mount 204. In the example of FIG. 3, a nose guard 300 is positioned along edges of the waveguide 216.

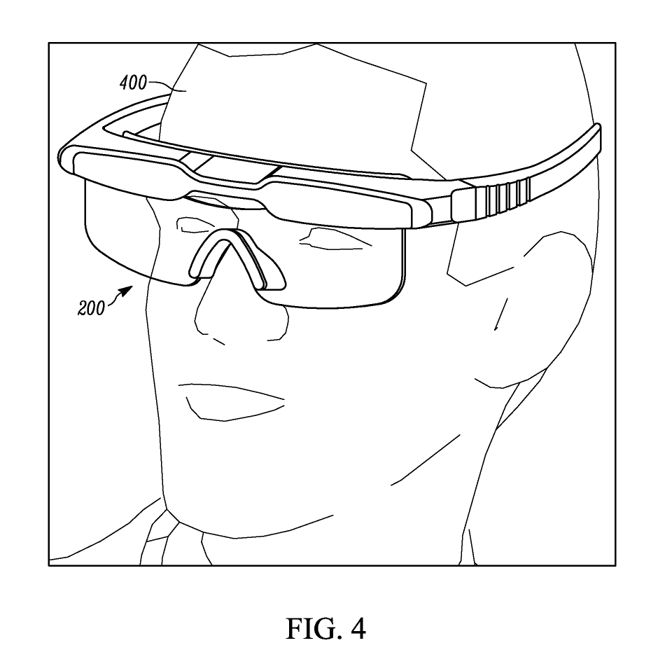

FIG. 4 illustrates the example HUD assembly 200 of FIG. 2A mounted to a head 400 of a user. As shown in FIG. 4, the positioning of the presentation generator 202 on the upper portion 214 of the HUD assembly 200 and the transmission of light in the direction 226 of FIG. 2A provides a clear field of view on the sides of the HUD assembly 200. That is, the example HUD assembly 200 of FIGS. 2-4 does not obstruct the field of view of the user. This contrasts with a HUD device having side-mounted light generators that interfere with the field of view of the user.

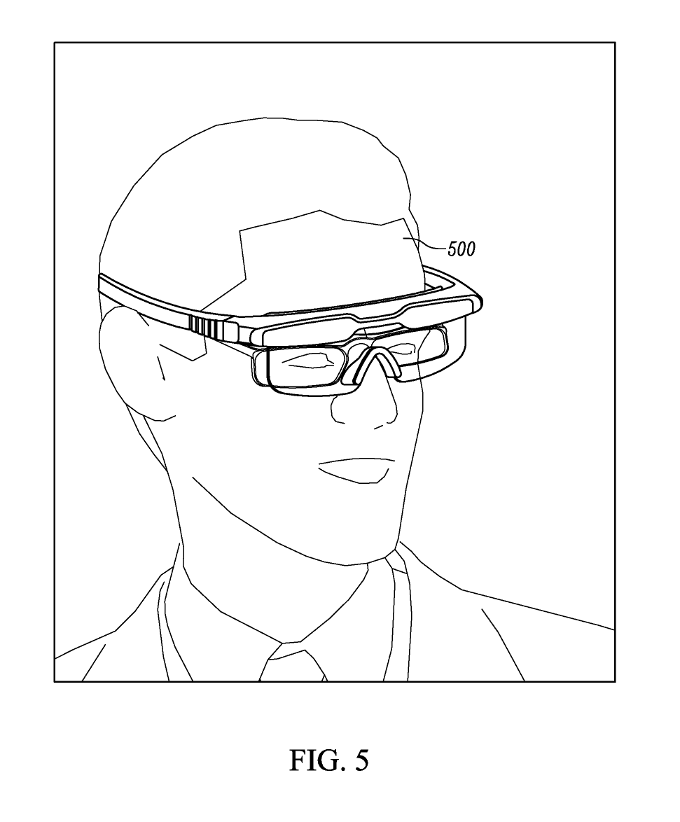

FIG. 5 illustrates the example HUD assembly 200 of FIG. 2A mounted to a head 500 of a user. As shown in FIG. 5, the positioning of the presentation generator 202 on the upper portion 214 of the HUD assembly 200 and the transmission of light in the direction 226 of FIG. 2A provides an ability to wear glasses and the HUD assembly 200 simultaneously. This contrasts with a HUD device having side-mounted light generators that restrict an ability to wear glasses simultaneously.

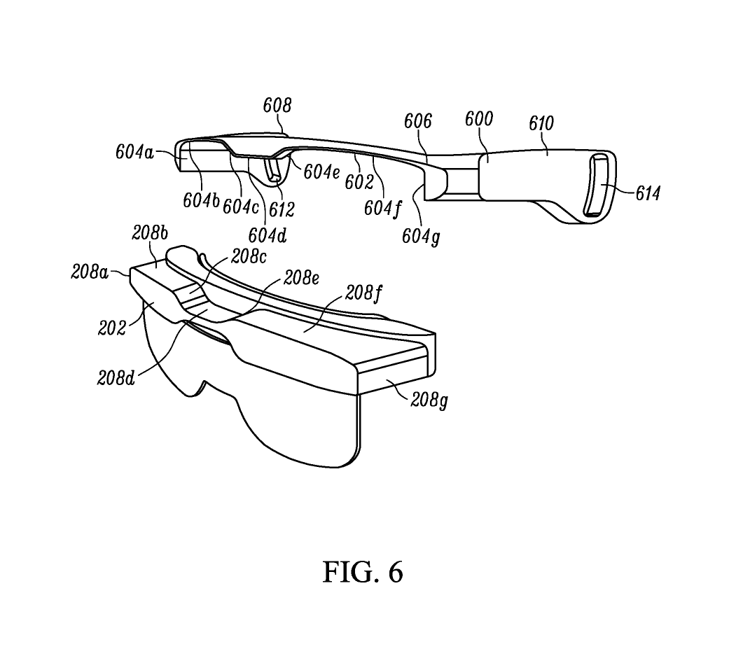

FIG. 6 illustrates another example head mount 600 configured to be mounted to the example presentation generator 200 of FIG. 2A. The example presentation generator 200 of FIG. 2A is reproduced in FIG. 6. Notably, the example head mount 600 of FIG. 6 and the example head mount 200 of FIG. 2A are both mountable to the example presentation generator 202. As such, the example head mount 600 of FIG. 6 is customized and/or tailored for a first environment (e.g., a healthcare setting) and/or application (e.g., working with inventory in a healthcare setting) while the example head mount 200 of FIG. 2A is customized and/or tailored for a second, different environment (e.g., warehouse) and/or application (e.g., working with inventory in a warehouse).

In the illustrated example of FIG. 6, the head mount 600 includes a mating surface 602 having interface structures 604 (e.g., particularly shaped surfaces) configured to matingly engage the interface structures 208 of the presentation generator 202. In the illustrated example of FIG. 6, the interface structures 604 of the head mount 600 are counterpart structures to the interface structures 208 of the presentation generator 202. In the illustrated example of FIG. 6, the mating surface 602 extends in a plurality of directions that are counterpart directions to the corresponding ones of the interface structures 208 of the mating surface 210 of the presentation generator 202. The directions in which the interface structures 604 of FIG. 6 extend correspond to the directions in which the interface structures 224 of FIG. 2A extend.

When mated, the example interface structures 208 of the presentation generator 202 and the interface structures 604 of the head mount 600 of FIG. 6 cooperate to removably couple the head mount 600 to the presentation generator 202. In some examples, the interface structures 208 of the presentation generator 202 and the interface structures 604 of the head mount 600 are configured for a friction fit such that a threshold amount of force is required to decouple the presentation generator 202 from the head mount 600. In some examples, the interface structures 208 of the presentation generator 202 and/or the interface structures 604 of the head mount 600 include one or more retaining members (e.g., tabs, hooks, and/or male/female engagements) to implement a threshold amount of force required to decouple the presentation generator 202 from the head mount 600. In some examples, one or more of the interface structures 208 of the presentation generator 202 and/or one or more of the interface structures 604 of the head mount 600 includes a release element such as, for example, a latch or pin that is engaged (e.g., pressed or moved) to disengage the presentation generator 202 from the head mount 600.

In the example of FIG. 6, the mating surface 602 and the interface structures 604 thereof make up a coupler 606 that enables first and second rails 608 and 610 to be simultaneously coupled to the presentation generator 202. This contrasts with known glasses in which in which individual rails are detached from a frame one at a time by removing different screws coupling the individual rails to the frame. In some examples, the coupler 606 and the first and second rails 608 and 610 form a modular sub-assembly. That is, the example coupler 606 of FIG. 6 may enable different types of rails to be removably coupled thereto. Alternatively, the example coupler 606 and the first and second rails 608 and 610 may form a one-piece (e.g., a singularly manufactured piece of material or an integrally formed piece of material) head mount 600.

In the example of FIG. 6, the first rail 608 includes a first aperture 612 and the second rail 610 includes a second aperture 614. The example first and second apertures 612 and 614 of FIG. 6 are configured to receive one or more straps capable of being mounted to, for example, a head of a user.

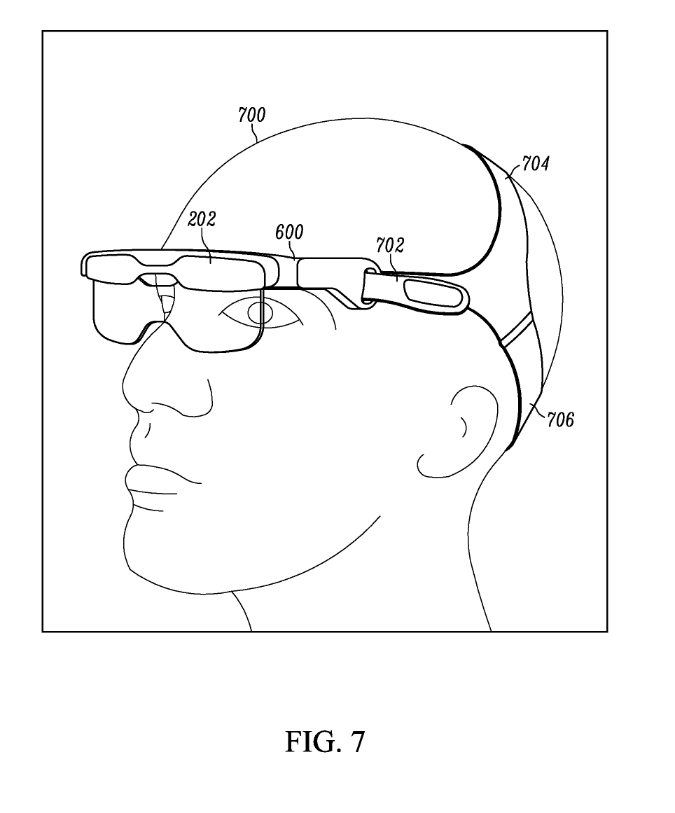

FIG. 7 illustrates the example heat mount 600 of FIG. 6 coupled to the example presentation generator 202 of FIGS. 2 and 6 and mounted to a head 700 of a user. In the example of FIG. 7, a strap 702 is placed through the apertures 612 and 614 of the head mount 600 and one portion of the strap 702 is adhered to another portion of the strap 702 to fasten the head mount 600 to the head 700. The example strap 700 of FIG. 7 includes a first rigid material 704 (e.g., plastic) and a second flexible material 706 to accommodate different sized heads.

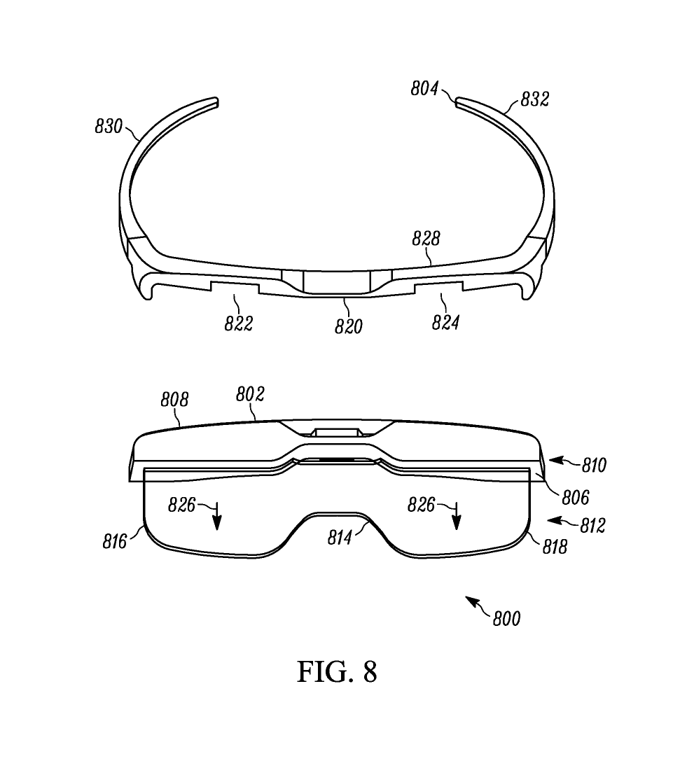

FIG. 8 illustrates an example HUD assembly 800 that may implement the example HUD assembly 100 of FIG. 1. The example HUD assembly 800 of FIG. 8 includes a presentation generator 802 and an example head mount 804. The example presentation generator 802 of FIG. 8 houses or carries components configured to generate, for example, an audiovisual presentation for consumption by a user wearing the example HUD assembly 800 of FIG. 8. For example, the presentation generator 802 of FIG. 2A houses or carries the components of the example presentation generator 102 of FIG. 1.

In the example of FIG. 8, the presentation generator 802 is configured to be coupled with different head mounts such as, for example, the head mount 804 of FIG. 8. That is, the example presentation generator 802 includes a modular form factor such that more than one type of head mount is attachable to the presentation generator 802. In the illustrated example, a housing 806 of the presentation generator 802 includes one or more interface structures positioned along a mating surface 808. Put another way, the example interface structures of FIG. 8 are portions of the mating surface 808. In the example of FIG. 8, the mating surface 808 is located on an upper portion 810 of the presentation generator 802. That is, the upper portion 810 of FIG. 8 is located above or over a lower portion 812 of the HUD assembly 800. In the example of FIG. 8, the lower portion 812 includes an optical waveguide 814 coupled to the housing 806. In the example of FIG. 8, at least a portion of the mating surface 808 is located on a first side of the housing 806 and the waveguide 814 is coupled to and/or extends from to a second side of the housing 806 opposing the first side. Moreover, the example HUD assembly 800 of FIG. 8 is said to have first and second side edges 816 and 818, which each extend along the waveguide 814 and the housing 806.

The example interface structures of the mating surface 808 of FIG. 8 are keying features or keying elements that cooperate with counterpart keying features or keying elements of a counterpart structure (e.g., a peripheral module). In the illustrated example of FIG. 8, the interface structures define receptacles and/or protrusions that interface with counterpart receptacles and/or protrusions of the counterpart structure (e.g., a peripheral module). In the illustrated example of FIG. 8, the head mount 804 includes a mating surface 820 having a first interface structure 822 configured to matingly engage a counterpart interface structure of the presentation generator 802. In the illustrated example of FIG. 8, the first interface structures 822 of the head mount 804 is a particularly shaped receptacle configured to receive a particularly shaped protruding interface structure of the presentation generator 802. Additionally, the example head mount 804 of FIG. 8 includes a second interface structure 824 along the mating surface 820 that is configured to matingly engage a counterpart interface structure of the presentation generator 802. The second interface structure 824 of the head mount 804 is a particularly shaped receptacle configured to receive a particularly shaped protruding interface structure of the presentation generator 802. In the example of FIG. 8, the first and second interface structures 822 and 824 (and the counterpart interface structures of the presentation generator 802) are similarly sized and shaped. In some examples, the first interface structure 822 differs from the second interface structure 824 in shape and/or size. In the example of FIG. 8, the first and second interface structures 822 and 824 (and the counterpart interface structures of the presentation generator 802) are symmetrically spaced from, for example, a center or midpoint of the mating surface 820. In some examples, the first and second interface structures 822 and 824 (and the counterpart interface structures of the presentation generator 802) are asymmetrically spaced from, for example, a center or midpoint of the mating surface 820. In addition to the protrusion portions that are configured to mate with the first and second interface structures 822 and 824, the mating surface 808 of the presentation generator 802 extends in a plurality of directions that are counterpart directions to the corresponding interface portions of the mating surface 820 of the head mount 804.

When mated, the example interface structures of the presentation generator 802 and the interface structures of the head mount 804 (e.g., the first and second interface structures 822 and 824) cooperate to removably couple the head mount 804 to the presentation generator 802. In some examples, the interface structures of the presentation generator 802 and the interface structures (e.g., the first and second interface structures 822 and 824) of the head mount 804 are configured for a friction fit such that a threshold amount of force is required to decouple the presentation generator 802 from the head mount 804. In some examples, the interface structures of the presentation generator 802 and/or the interface structures of the head mount 804 include one or more retaining members (e.g., tabs, hooks, and/or male/female engagements) to implement a threshold amount of force required to decouple the presentation generator 802 from the head mount 804. In some examples, one or more of the interface structures of the presentation generator 802 and/or one or more of the interface structures of the head mount 804 includes a release element such as, for example, a latch or pin that is engaged (e.g., pressed or moved) to disengage the presentation generator 802 from the head mount 804.

In the example of FIG. 8, the housing 806 of the presentation generator 802 carries light engines (not shown in FIG. 8) (e.g., the light engines 108 of FIG. 1) that generate light to be carried by the waveguide 814. In the illustrated example, the light engines direct the light across the waveguide 814 in a direction 826 away from the housing 806. Notably, in the example HUD assembly 800 of FIG. 8, the light engines are located above the waveguide 814 and the light is directed downward (as opposed to sideways). This position of the light engines contrasts with known light engines that are positioned on side edges of the corresponding HUD assembly. By locating the light engines in the housing 806 (e.g., in the upper portion 810 of the presentation generator 802) and above the waveguide 814, the example HUD assembly 800 of FIG. 8 does not obstruct the field of view of the user. For example, without light engines on the side edges 816 and 818, the user of the example HUD assembly 800 of FIG. 8 has full peripheral vision available in the field of view.

In the example of FIG. 8, the mating surface 820 and the interface structures thereof make up a coupler 828 that enables first and second rails 830 and 832 to be simultaneously coupled to the presentation generator 802. This contrasts with known glasses in which in which individual rails are detached from a frame one at a time by removing different screws coupling the individual rails to the frame. In some examples, the coupler 828 and the first and second rails 830 and 832 form a modular sub-assembly. That is, the example coupler 828 of FIG. 8 may enable different types of rails to be removably coupled thereto. Alternatively, the example coupler 828 and the first and second rails 830 and 832 may form a one-piece (e.g., a singularly manufactured piece of material or an integrally formed piece of material) head mount 804.

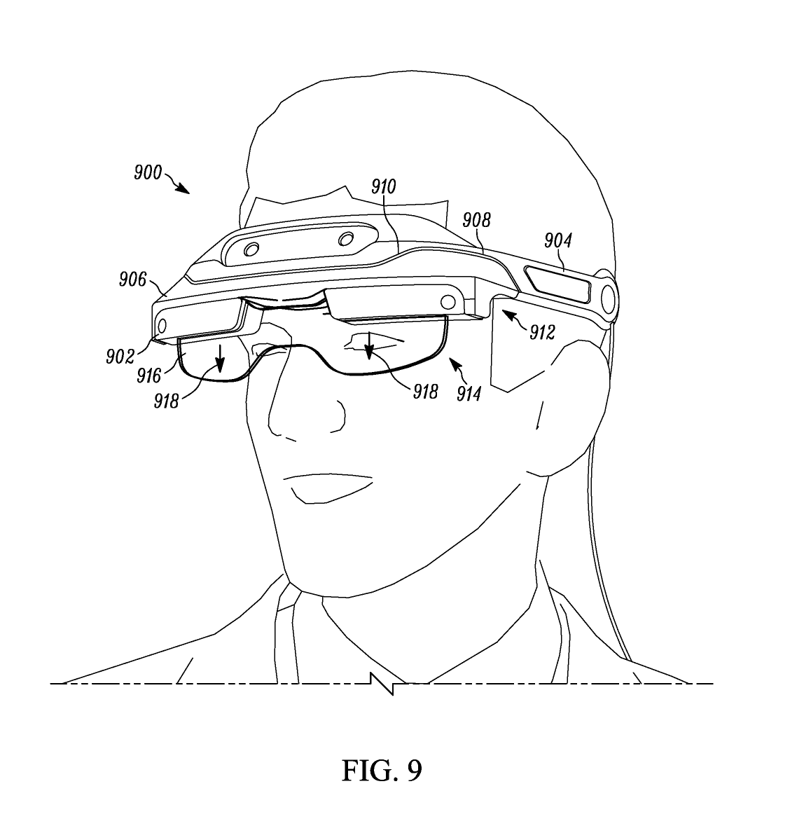

FIG. 9 illustrates an example HUD assembly 900 that may implement the example HUD assembly 100 of FIG. 1. The example HUD assembly 900 of FIG. 9 includes a presentation generator 902 and an example head mount 904. The example presentation generator 902 of FIG. 9 houses or carries components configured to generate, for example, an audiovisual presentation for consumption by a user wearing the example HUD assembly 900 of FIG. 9. For example, the presentation generator 902 of FIG. 9 houses or carries the components of the example presentation generator 102 of FIG. 1.

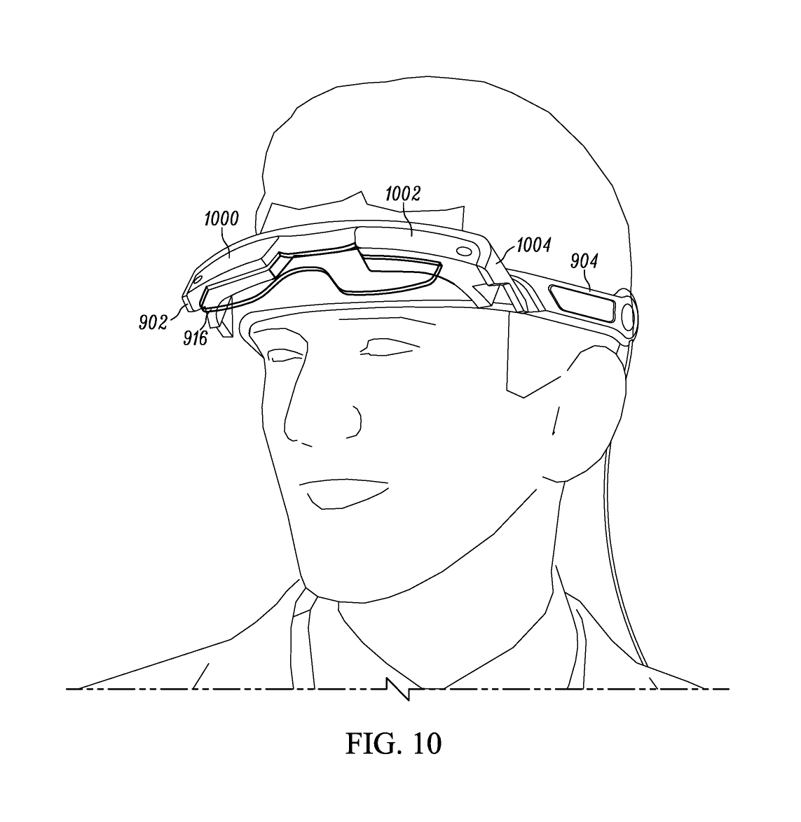

The example HUD assembly 900 of FIG. 9 is hingedly movable between a first position (e.g., an engaged position) in which a user can view the media displayed by the presentation generator 902, and a second position (e.g., a disengaged position) in which the user cannot view the media. The second position of the example HUD assembly 900 of FIG. 9 is shown in FIG. 10.

In the illustrated example of FIG. 9, a housing 906 of the presentation generator 902 is hingedly coupled to the head mount 904. A shape of a mating surface 908 of the presentation generator 902 corresponds to a shape of a mating surface 910 of the head mount 904. In some examples, the mating surfaces 908 and 910 includes one or more interface structures (e.g., particularly shaped surfaces that define protrusion(s) and/or receptacle(s)) that form keying features or keying elements that cooperate to interface the head mount 904 with the presentation generator 902.

In the example of FIG. 9, the mating surface 908 of the presentation generator 902 is located on an upper portion 912 of the presentation generator 902. That is, the upper portion 912 of FIG. 9 is located above or over a lower portion 914 of the HUD assembly 900. In the example of FIG. 9, the lower portion 914 includes an optical waveguide 916 coupled to the housing 906.

In the example of FIG. 9, the housing 906 of the presentation generator 902 carries light engines (not shown in FIG. 9) (e.g., the light engines 108 of FIG. 1) that generate light to be carried by the waveguide 916. In the illustrated example, the light engines direct the light across the waveguide 916 in a direction 918 away from the housing 906. Notably, in the example HUD assembly 900 of FIG. 9, the light engines are located above the waveguide 916 and the light is directed downward (as opposed to sideways). This position of the light engines contrasts with known light engines that are positioned on side edges of the corresponding HUD assembly. By locating the light engines in the housing 906 (e.g., in the upper portion 912 of the presentation generator 902) and above the waveguide 916, the example HUD assembly 900 of FIG. 9 does not obstruct the field of view of the user (e.g., as opposed to light engines located on side edges of the presentation generator).

As shown in FIG. 10, the presentation generator 902 is moved to the second position by pivoting the presentation generator 902 away from the eyes of the user. In example second position shown if FIG. 10, the presentation generator 902 overlaps the head mount 904 from a perspective directed at the user. Further, as shown in FIG. 10, the waveguide 916 is carried by first and second housings 1000 and 1002 that carry the light engines. A hinge mount 1004 of the presentation generator 902 carries the first and second housings 1000 and 1002 and cooperates with a hinge mechanism to move the presentation generator 902 between the first and second positions. In some examples, one or more detents or other suitable structures are utilized to retain the presentation generator 902 in the first and/or second positions in the absence of a threshold amount of force, which can overcome the detents.

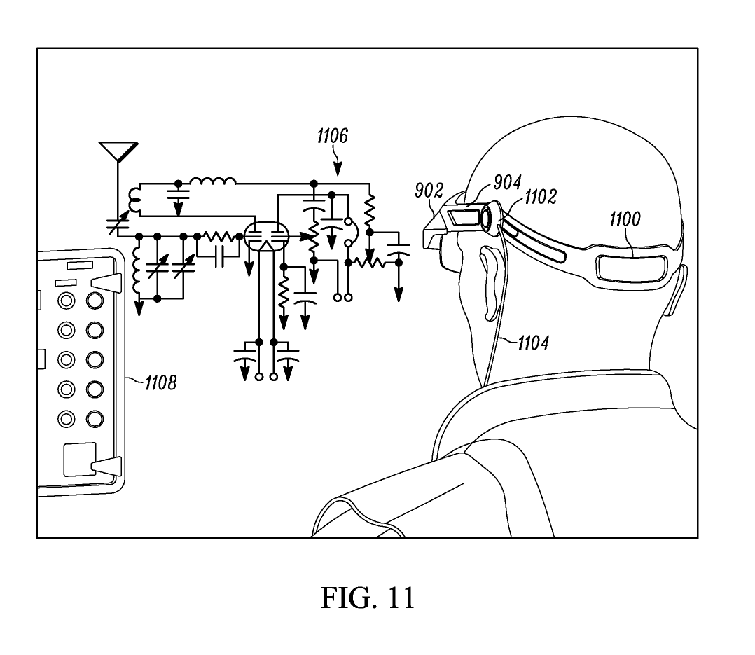

FIG. 11 illustrates an example strap 1100 attachable to the example head mount 904 of FIGS. 9 and 10. Additionally, FIG. 11 illustrates an example exit point 1102 of the head mount 904 to which a cable 1104 is routed or guided by structures of the head mount 904. The cable 1104 is, for example, a power cable in communication with a power element of the HUD assembly 900 or a data cable in communication with, for example, one of the interfaces 136. In some examples, the cable 1104 is coupled to a power source (e.g., battery) being worn by the user (e.g., on a belt). In particular, the example head mount 904 includes a one or more guides or routes positioned (e.g., internally or along an inside edge of the head mount 1104) along one or more of the rails of the head mount 904. As such, the example head mount 904 guides the cable 1104 to location in which the cable 1104 is unlikely to interfere with a working space in front of the user. That is, the example cable routing provided by the example head mount 904 prevents the cable 1104 for obstructing a view and/or workspace of the user. In some examples, the example cable routing of the example head mount 904 of FIGS. 9-11 is implemented in the example HUD assembly 200 of FIG. 2A, the example HUD assembly 600 of FIG. 6 and/or the example HUD assembly 800 of FIG. 8.

Additionally, FIG. 11 illustrates an example circuit diagram 1106 that is displayed to the user via the waveguide 916. The example circuit diagram 1106 is representative of, for example, an electronic device 1108 within the field of view of the user.

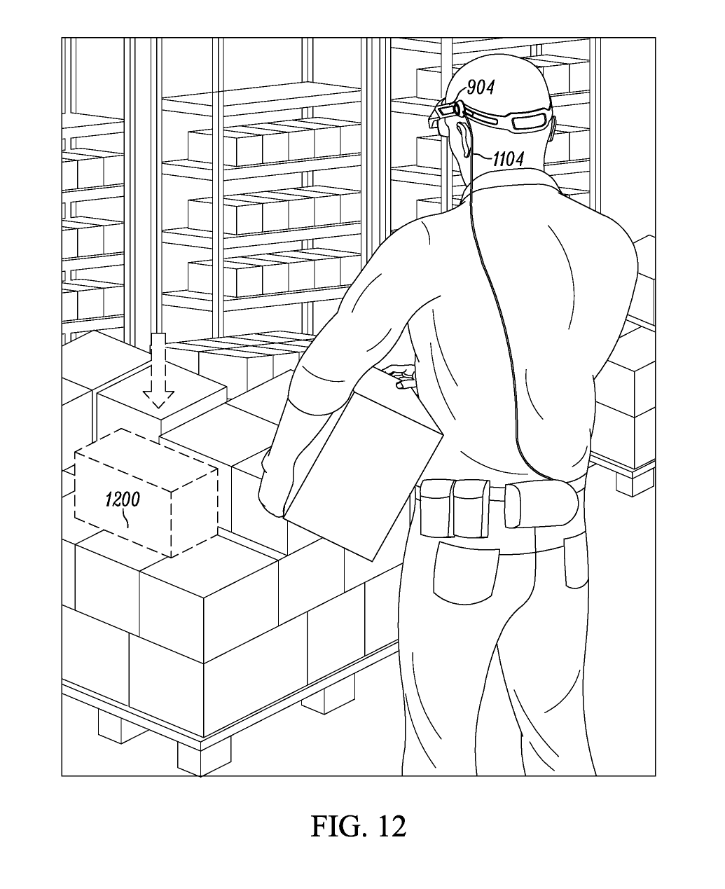

FIG. 12 illustrates the example cable 1104 of FIG. 11 being routed by the example head mount 904 along a back of the user to a device being carried by a belt of the user. Additionally, FIG. 12 illustrates an example placement indicator 1200 displayed to the user view the waveguide 916. The example placement indicator 1200 indicates to the user a placement of a currently held box. The placement represented by the placement indicator 1200 is based on, for example, an analysis performed by a logic circuit.

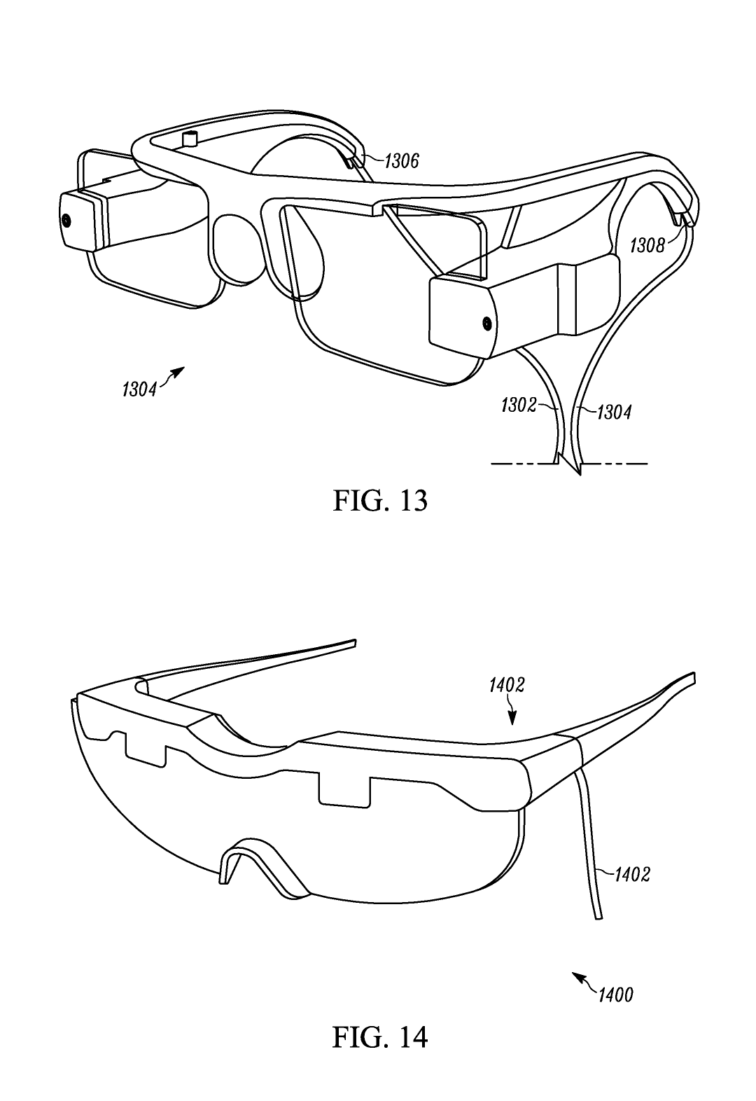

FIG. 13 illustrates an example HUD assembly 1300 having first and second cables 1302 and 1304 being routed to a rear of the HUD assembly 1300. In particular, the example HUD assembly 1300 includes internal guides terminating at first and second exit points 1306 and 1308 to position the first and second cables 1302 and 1304 at the rear of the HUD assembly 1300 and, thus, the head of the user when the HUD assembly 1300 is being worn. That is, the first and second exit points 1306 and 1308 direct the first and second cables 1302 and 1304, respectively, away from a front of the HUD assembly 1300.

FIG. 14 illustrates an example HUD assembly 1400 having a communication port 1402 positioned to route a cable 1400 routed away from a front of the HUD assembly 1400. The communication port 1402 is in communication with, for example, a power element (e.g., battery) of the HUD assembly 1400 or a data source, such as the interfaces 136 of FIG. 1.

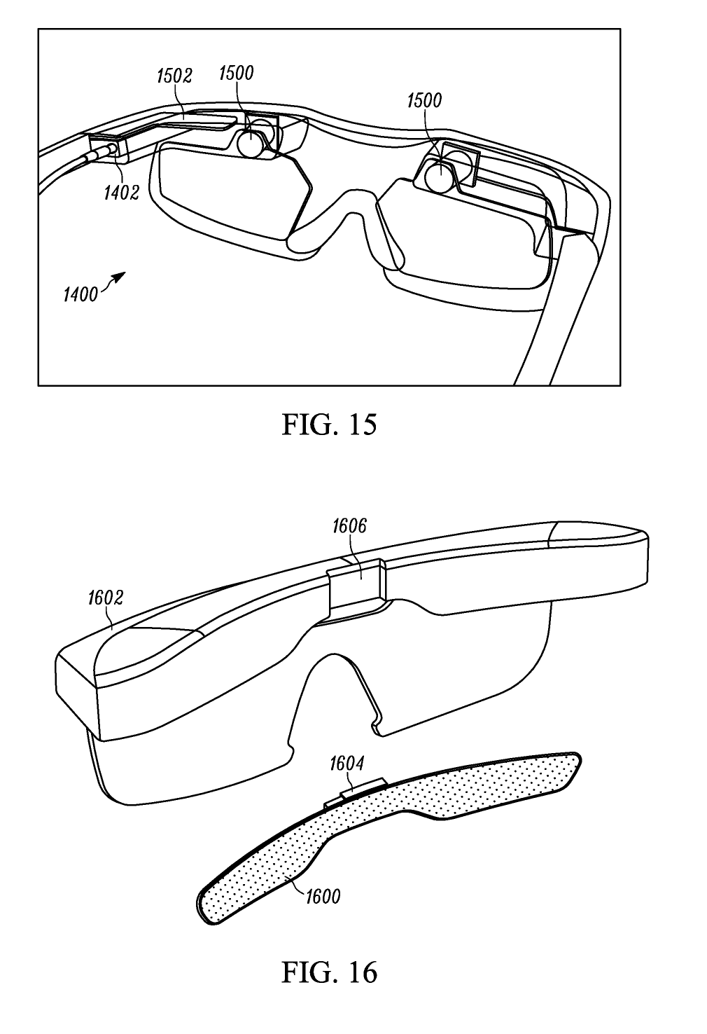

FIG. 15 illustrates an example position for the communication port 1402 of FIG. 14. Additionally, FIG. 15 illustrates example light engines 1500 that implement, for example, the light engines 108 of FIG. 1. Additionally, FIG. 15 illustrates an example camera 1502 that implements, for example, the camera 130 of FIG. 1.

FIG. 16 illustrates an example pad 1600 configured for use with an example presentation generator 1602 (e.g., the example presentation generator 202 of FIG. 2A, the example presentation generator 600 of FIG. 6 and/or the example presentation generator 900 of FIG. 9). The example pad 1600 of FIG. 16 includes a protrusion 1604 configured to engage a counterpart receptacle 1606 of the presentation generator 1602. In some examples, the protrusion 1604 is configured to friction fit into the receptacle 1606. However, any suitable interface components are possible for the example pad 1600 and the example presentation generator 1602.

When the example presentation generator 1602 of FIG. 16 is mounted to a head of a user, the example pad 1600 of FIG. 16 is positioned between the head and the presentation generator 1602. That is, the pad 1600 is in contact with the head of the user, rather than the presentation generator 1602 being in contact with the head of the user. Accordingly, the example pad 1600 of FIG. 16 enhances comfort of the user and provides hygienic benefits to groups of users sharing the presentation generator 1602.

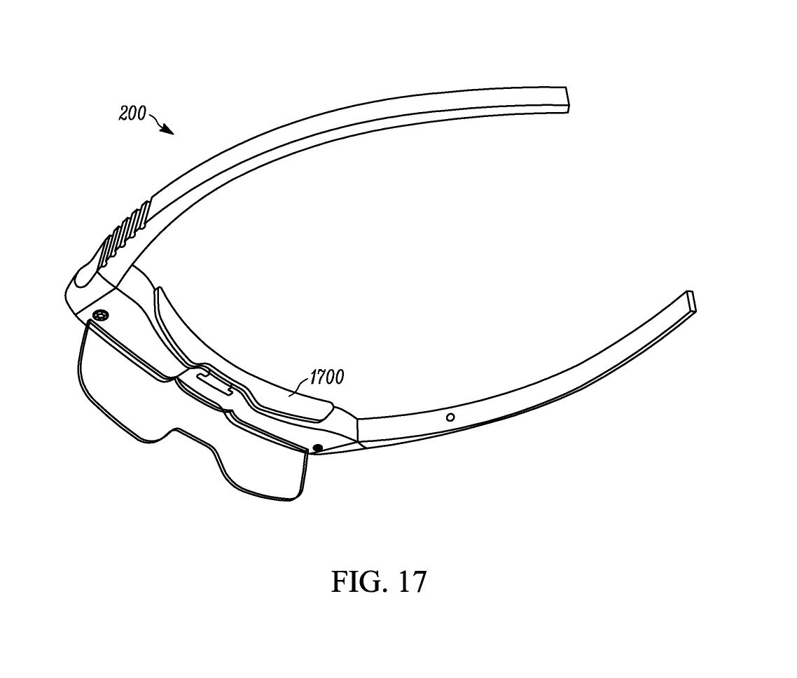

FIG. 17 illustrates the example pad 1600 of FIG. 16 installed on the example HUD assembly 200 of FIG. 2A described above.

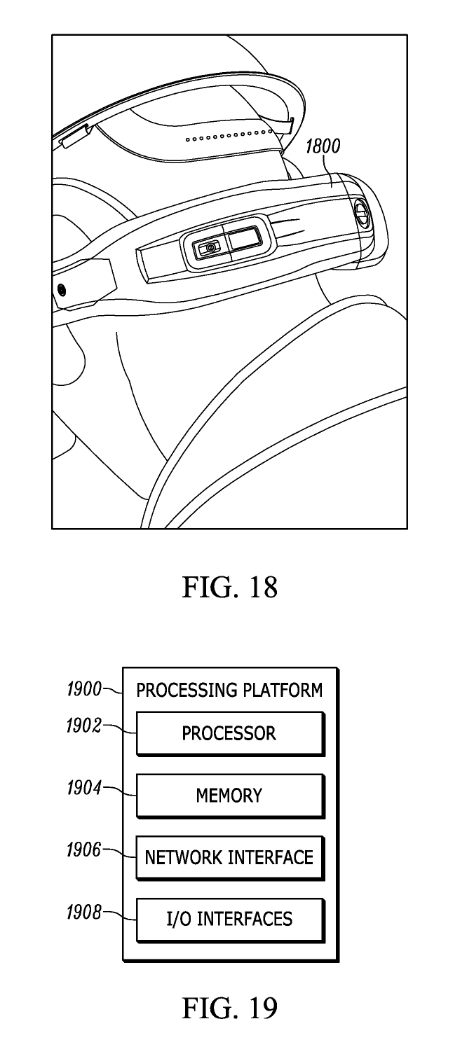

FIG. 18 illustrates a power source 1800 mountable to, for example, the example HUD assemblies disclosed herein. The example power source 1800 of FIG. 18 enables operation of the corresponding HUD assembly without the HUD assembly being wired to, for example, a power source carried by a belt of the user. The example power source 1800 of FIG. 18 is proximate the rear of the head of the user. As this area is not likely occupied and as this area is not a working space (e.g., an area in which hands of the user carry out tasks), the example power source 1800 is not obstructive. Additionally, as this area is not likely occupied and as this area is not a working space, the example power source 1800 is able to employ a large power component (e.g., battery), thereby provided extended operational amounts of time for the HUD assembly.

FIG. 19 is a block diagram representative of an example logic circuit that may utilized to implement, for example, the example image generator 106, the example light engines 108, one or more of the example interfaces 136 and/or the example audio generator 112 of FIG. 1. The example logic circuit of FIG. 19 is a processing platform 1900 capable of executing machine-readable instructions to, for example, implement operations associated with the example HUD assembly 100 of FIG. 1.

The example processing platform 1900 of FIG. 19 includes a processor 1902 such as, for example, one or more microprocessors, controllers, and/or any suitable type of processor. The example processing platform 1900 of FIG. 1900 includes memory (e.g., volatile memory, non-volatile memory) accessible by the processor 1902 (e.g., via a memory controller). The example processor 1902 interacts with the memory 1904 to obtain, for example, machine-readable instructions stored in the memory 1904. Additionally or alternatively, machine-readable instructions may be stored on one or more removable media (e.g., a compact disc, a digital versatile disc, removable flash memory, etc.) that may be coupled to the processing platform 1900 to provide access to the machine-readable instructions stored thereon.

The example processing platform 1900 of FIG. 19 includes a network interface 1906 to enable communication with other machines via, for example, one or more networks. The example network interface 1906 includes any suitable type of communication interface(s) (e.g., wired and/or wireless interfaces) configured to operate in accordance with any suitable protocol(s).

The example processing platform 1900 of FIG. 19 includes input/output (I/O) interfaces 1908 to enable receipt of user input and communication of output data to the user.

Although certain example apparatus, methods, and articles of manufacture have been disclosed herein, the scope of coverage of this patent is not limited thereto. On the contrary, this patent covers all apparatus, methods, and articles of manufacture fairly falling within the scope of the claims of this patent.

1. An apparatus, comprising:
a housing to carry an image generator;
a display surface extending from a first side of the housing; and
a mating surface along a second side of the housing opposing the first side of the housing, the mating surface to removably couple a head mount to the housing.

2. An apparatus as defined in claim 1, wherein the mating surface is positioned above the display surface when the apparatus is mounted to a head of a user.

3. An apparatus as defined in claim 1, wherein the housing is positioned above the display surface when the apparatus is mounted to a head of a user.

4. An apparatus as defined in claim 1, wherein the mating surface defines:
a first base element;
a second base element; and
a receptacle between the first and second base elements.

5. An apparatus as defined in claim 4, wherein the receptacle is shaped to be engaged by a protrusion of the head mount.

6. An apparatus as defined in claim 1, wherein the mating surface defines:
a first protrusion;
a second protrusion; and
a surface between the first and second protrusions. Page 2 of 7

7. An apparatus as defined in claim 1, wherein the mating surface defines a first plurality of interface structures extending in a first direction and a second plurality of interface structures extending in a second direction different than the first direction.

8. An apparatus as defined in claim 7, wherein the first direction is a vertical direction and the second direction is a horizontal direction.

9. An apparatus as defined in claim 7, wherein the mating surface defines a third plurality of interface structures extending in a third direction.

10. An apparatus as defined in claim 9, wherein the third direction is at an angle relative to the first and second directions.

11. An apparatus as defined in claim 1, wherein the image generator includes:
a first light engine to provide light to the display surface; and
a second light engine to provide light to a second display surface.

12. An apparatus as defined in claim 1, wherein the mating surface includes a plurality of particularly shaped surfaces to enable a friction fit with counterpart particularly shaped surfaces of the head mount.

13. An apparatus as defined in claim 1, further comprising a receptacle adapted to removably receive a pad shaped to contact a head of the user.

14. An apparatus, comprising:
a first rail;
a second rail; and
a coupler extending between the first and second rails, the coupler including a mating surface to removably couple the first and second rails to a housing of a presentation generator.

15. An apparatus as defined in claim 14, wherein the mating surface defines:
a first base element;
a second base element; and
a protrusion between the first and second base elements.

16. An apparatus as defined in claim 15, wherein the protrusion is shaped to engage a receptacle of a second mating surface of the housing of the presentation generator.

17. An apparatus as defined in claim 14, wherein the mating surface defines:
a first receptacle;
a second receptacle; and
a surface between the first and second receptacles.

18. An apparatus as defined in claim 14, wherein the mating surface defines a first plurality of interface structures extending in a first direction and a second plurality of interface structures extending in a second direction different than the first direction.

19. An apparatus as defined in claim 18, wherein the first direction is a vertical direction and the second direction is a horizontal direction.

20. An apparatus as defined in claim 18, wherein the mating surface defines a third plurality of interface structures extending in a third direction.

21. An apparatus as defined in claim 20, wherein the third direction is at an angle relative to the first and second directions.

22. An apparatus as defined in claim 14, wherein the first rail includes a first aperture to receive a strap, and the second rail includes a second aperture to receive the strap.

23. A wearable media presentation assembly comprising:
a presentation generator including:
a housing to carry an image generator;
a display surface extending from a first side of the housing; and
a first mating surface along a second side of the housing opposing the first side of the housing, the first mating surface including a first interface structure; and
a mount including:
a first rail;
a second rail; and
a coupler extending between the first and second rails, the coupler including a second mating surface including a second interface structure, the second interface structure being a counterpart of the first interface structure.

24. (canceled)

25. (canceled)

26. (canceled)

27. (canceled)

28. (canceled)
